(19) United States
(12) Patent Application Publication
(10) Pub. No.: US 2016/0276249 A1
(43) Pub. Date: Sep. 22, 2016

(54) SEMICONDUCTOR DEVICE

(71) Applicant: KABUSHIKI KAISHA TOSHIBA, Tokyo (JP)

(72) Inventor: Shiro OKADA, Sagamihara Kanagawa (JP)

(21) Appl. No.: 15/060,543

(22) Filed: Mar. 3, 2016

(30) Foreign Application Priority Data
Mar. 16, 2015 (JP) 2015-052733

(51) Int. Cl. H01L 23/495; H01L 21/48; H01L 21/56; H01L 23/31

(52) U.S. Cl. CPC H01L 23/49513; H01L 23/4952; H01L 23/49541; H01L 23/49582; H01L 23/3114; H01L 21/4825; H01L 21/565

(57) ABSTRACT

A semiconductor device includes a mounting member that includes first and second regions. First peripheral portions are provided along at least a portion of an outer periphery of the first region. A second peripheral portion is provided between at least one first peripheral portion and at least another first peripheral portion. The first peripheral portions and second peripheral portion are provided in the second region. A partition wall is provided at least on one of the first peripheral portions. A semiconductor chip is mounted on the first region via solder.

### CROSS-REFERENCE TO RELATED APPLICATION

This application is based upon and claims the benefit of priority from Japanese Patent Application No. 2015-052733 filed Mar. 16, 2015, the entire contents of which are incorporated herein by reference.

### FIELD

Embodiments described herein relate generally to a semiconductor device.

### BACKGROUND

As one die bonding methodology for mounting a semiconductor chip on a mounting member such as a lead frame, the method of joining the semiconductor chip and the lead frame by using solder paste is known.

In a case of joining the semiconductor chip and the lead frame using solder paste, positional deviation (in a case where one direction of a joining surface of the semiconductor chip is set as an X direction, a direction perpendicular to the X direction in the joining surface of the semiconductor chip is set as a Y direction, and a direction perpendicular to an XY direction is set as a Z direction, positional deviation in a rotational direction with the Z direction set as an axis) of the semiconductor chip in a rotational direction tends to occur with respect to the axis that is perpendicular to the joining surface of the semiconductor chip, and thus it is difficult to increase the positional accuracy of the semiconductor chip on the lead frame. In other words, the chip becomes skewed with respect to the joining surface of the underlying lead frame mounting area.

As a method of suppressing positional deviation of the semiconductor chip on the lead frame, for example, there is known a method of reducing an amount of the solder paste, or a method of providing a groove in the mounting surface of the lead frame so as to allow surplus solder to flow into the groove. However, using these methods, a soldering material that joins the lead frame and the semiconductor chip may become too thin.

As a method of suppressing the positional deviation of the semiconductor chip on the lead frame, there is also known a method of forming a region on the lead frame using a laser, which region has lower wettability compared to the mounting region, so as to suppress undesired spreading of the solder from the chip mounting area of the lead frame. However, a material such as copper, which is used in the lead frame, has a low absorption rate with respect to a high-frequency laser such as a YAG laser, and the absorbtion rate may be further reduced by a flux contained in the solder paste. Accordingly, in the method, it may be difficult to sufficiently suppress undesired spreading of the solder.

### DESCRIPTION OF THE DRAWINGS

FIG. 1 is a schematic plan view illustrating a structure example of a semiconductor device.

FIG. 2 is a schematic cross-sectional view illustrating the structure example of the semiconductor device.

FIG. 3 is a schematic plan view illustrating another structure example of the semiconductor device.

FIG. 4 is a schematic plan view illustrating still another structure example of the semiconductor device.

FIG. 5 is a schematic plan view illustrating still another structure example of the semiconductor device.

FIG. 6 is a schematic plan view illustrating still another structure example of the semiconductor device.

FIG. 7 is a schematic plan view illustrating still another structure example of the semiconductor device.

FIG. 8 is a schematic plan view illustrating still another structure example of the semiconductor device.

FIG. 9 is a schematic plan view illustrating still another structure example of the semiconductor device.

### DETAILED DESCRIPTION

In general, according to one embodiment, a semiconductor device, includes a mounting member having first and second regions, a plurality of first peripheral portions provided along at least a portion of an outer periphery of the first region, and a second peripheral portion provided between at least one of the plurality of first peripheral portions and at least another of the plurality of first peripheral portions. The plurality of first peripheral portions and the second peripheral portion are provided in the second region. A partition wall is provided on at least one of the first peripheral portions. A semiconductor chip is provided on the first region via a solder.

Hereinafter, an embodiment will be described with reference to the accompanying drawings. In addition, the drawings are schematic, and for example, the relationship between a thickness and planar dimensions, a thickness ratio of respective layers, and the like may be different from actual values of an actual device. In addition, in the respective embodiments, the same reference numeral will be given to substantially the same structural elements, and description thereof will not be repeated where appropriate.

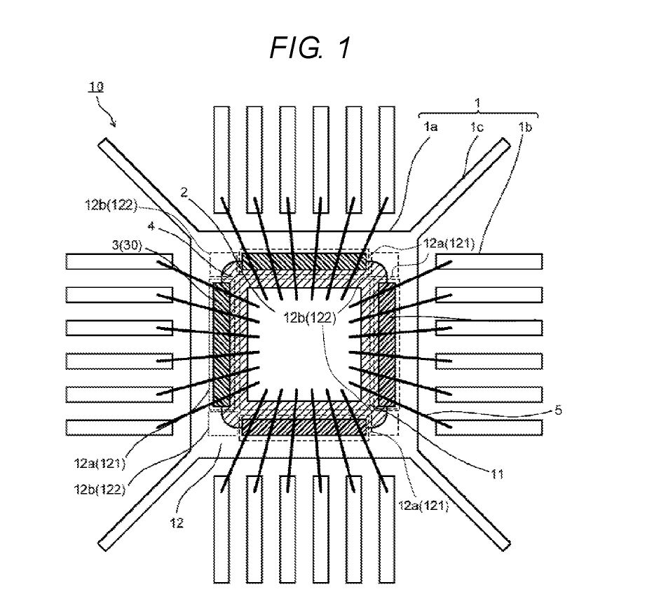

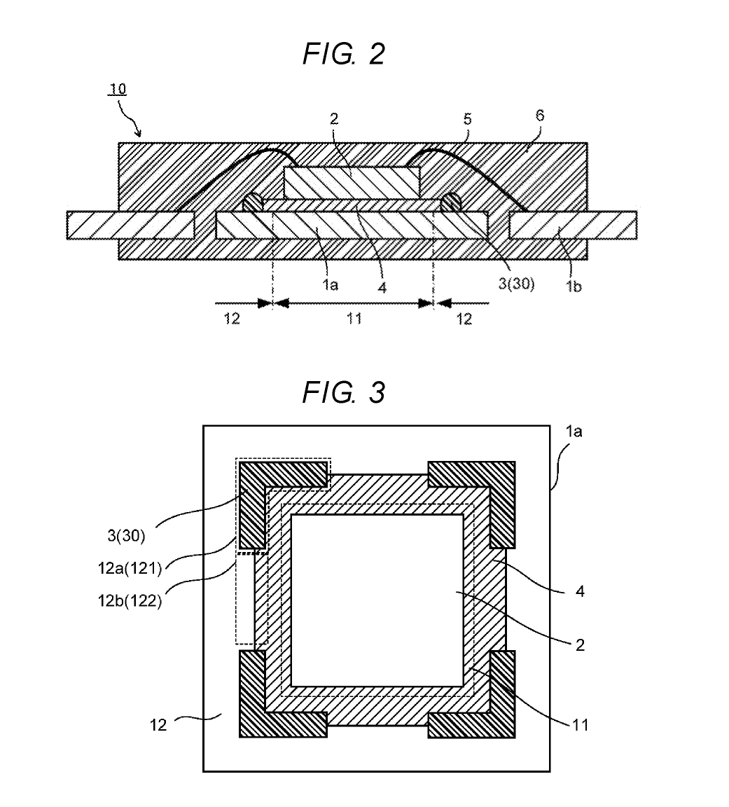

FIGS. 1 and 2 are views illustrating a structure example of a semiconductor device, in which FIG. 1 is a schematic plan view and FIG. 2 is a schematic cross-sectional view of the device. A semiconductor device 10 illustrated in FIGS. 1 and 2 includes a mounting member 1, a semiconductor chip 2, a partition wall layer 3, a soldering material 4, a bonding wire 5, and a resin layer 6. In addition, in FIG. 1, the resin layer 6 is omitted for convenience.

The mounting member 1 has a first surface (upper surface of the mounting member 1), and a second surface (lower surface of the mounting member 1) that is opposite to the first surface. As the mounting member 1, for example, a metal sheet such as a lead frame including copper, a copper alloy, an alloy of iron and nickel such as alloy 42, and the like may be used. For example, when using a lead frame which uses copper which is exposed as the first surface, it is possible to increase the heat removal properties of the semiconductor device. In FIG. 1, each of the first surface and the second surface is divided into at least three regions of a chip mounting portion 1a, a lead portion 1b, and a support pin portion 1c.

The chip mounting portion 1a is a region of the mounting member 1 on which the semiconductor chip 2 is mounted. Although the flat surface of the chip mounting portion 1a as depicted has a rectangular shape, it is not limited to this shape. The chip mounting portion 1a has a central region 11 and a surrounding region 12 that surrounds the central region 11.

The central region 11 is the chip mounting region, and the surrounding region 12 is a peripheral region of the chip mounting region. The surrounding region 12 includes a plurality of peripheral portions 12a which are provided along at least a portion of the outer periphery of the region 11, and a peripheral portion 12b that is provided between at least one of the peripheral portions 12a and at least another of the peripheral portions 12a. Each of the peripheral portions 12a is a region configured to block the soldering material 4 from flowing therepast. The peripheral region 12b is configured to allow the soldering material to flow therethrough.

The plurality of peripheral portions 12a include a plurality of first unit regions 121 which are provided to be spaced from each other along the outer periphery of the region 11. The plurality of peripheral portions 12a illustrated in FIG. 1 includes four first unit regions 121, each being provided along a different side of the semiconductor chip 2, such that a first unit region is alongside each side of the semiconductor chip 2. At this time, one of the first unit regions 121 may be regarded as one of the peripheral regions 12a.

In addition, the peripheral portion 12b includes a plurality of second unit regions 122, each being provided between the plurality of first unit regions 121. The peripheral portion 12b, which is illustrated in FIG. 1, includes four second unit regions 122, each being provided at a corner of the semiconductor chip 2. The peripheral portion 12b comes into contact with the resin layer 6 or comes into contact with the soldering material 4.

The lead portions 1b forms a lead, i.e. a conductor for electrical connection to and from the semiconductor device. Each lead portion 1b is provided at a peripheral portion of the chip mounting portion 1a. Each lead portion 1b is physically spaced from the chip mounting portion 1a. In FIG. 1, although a plurality of the lead portions 1b are provided on the upper and lower sides, and on the right and left sides of the chip mounting portion 1a, respectively, there is no limitation on the number thereof.

The support pin portion 1c supports the chip mounting portion 1a during manufacturing. In FIG. 1, although the support pin portion 1c extends outwardly from a corner of the chip mounting portion 1a, it is not limited to this location and configuration. For example, the support pin portion 1c may extend outwardly from one side of a peripheral edge of the chip mounting portion 1a. In addition, a portion of the support pin portion 1c may be removed during manufacturing.

The semiconductor chip 2 is mounted on the first surface. In FIG. 1, the semiconductor chip 2 is mounted on the region 11. In FIG. 1, although the semiconductor chip 2 has a rectangular shape, the shape is not limited thereto.

The partition wall layer 3 is provided on the first surface. In FIG. 1, the partition wall layer 3 contacts at least the peripheral portion 12a of the chip mounting portion 1a. The partition wall layer 3 includes a plurality of unit layers 30, and one of each is provided on each of the plurality of first unit regions 121. A gap between the semiconductor chip 2 and the partition wall layer 3 may be, for example, in a range of from 0.05 mm to 0.4 mm.

The thickness of the partition wall layer 3 is preferably greater than the thickness of the soldering material 4. As a result, the partition wall layer forms a dam which prevents the soldering material 4 from flowing thereover. As the partition wall layer 3, for example, ink, a thermosetting resin such as a solder resist, an ultraviolet curable resin, and the like may be used. In addition, as the partition wall layer 3, for example, a polyimide resin, an epoxy resin, and the like may be used. In addition, the partition wall layer 3 may be configured to repel solder. For example by performing surface processing with respect to the partition wall layer 3, the partition wall layer may be “hydrophobic” to the solder, i.e., the solder will not adhere thereto.

The partition wall layer 3 is formed at a location spaced from the soldering material 4 before the joining together of the mounting member 1 and the semiconductor chip 2. For example, the partition wall layer 3 may be formed by applying a material layer using a method such as writing, stamping, and inkjet processing, and then curing the layer with heat or ultraviolet rays.

The soldering material 4 joins the mounting member 1 and the semiconductor chip 2. In FIG. 1, the soldering material 4 is provided between the region 11 and the semiconductor chip 2, and is adhered or bonded to the central region 11 and to the semiconductor chip 2. That is, the semiconductor chip 2 is securely mounted on the central region 11 via the soldering material 4. As the soldering material 4, for example, tin-silver-based lead-free solder, tin-silver-copper-based lead-free solder, and the like may be used.

The soldering material 4 may widely spread outward from the periphery of the semiconductor chip 2. In FIG. 1, although the soldering material 4 comes into contact with the partition wall layer 3, the solder may also be spaced therefrom. In addition, the soldering material 4 may also overlie or extend past the peripheral portion 12b. For example, the soldering material 4 is formed as follows. After forming the partition wall layer 3, solder paste is applied by using a dispenser and the like. After the semiconductor chip 2 is placed on the solder paste on the central region 11, the solder paste is melted, thereby forming the soldering material 4.

The bonding wire 5 electrically connects the mounting member 1 to the semiconductor chip 2. In FIGS. 1 and 2, one end of the bonding wire 5 is joined to the lead portion 1b, and the other end is joined to a connection pad of the semiconductor chip 2. For example, the bonding wire 5 is formed after joining together the mounting member 1 and the semiconductor chip 2 by the soldering material 4.

The resin layer 6 is provided on the first surface and the second surface of the mounting member 1 so as to seal semiconductor chip 2 therein. In FIG. 1, the resin layer 6 is provided on the first surface and the second surface of the mounting member 1 so as to cover the semiconductor chip 2, the partition wall layer 3, the soldering material 4, and the bonding wire 5. At this time, a portion of the lead portion 1b is exposed by extending outwardly from the resin layer 6. The resin layer 6 is formed after the process of forming the bonding wire 5. For example, the resin layer 6 may be formed by forming a first resin layer on the first surface so as to seal the semiconductor chip 2, and by forming a second resin layer on the second surface.

The resin layer 6 contains at least an inorganic filler such as SiO₂. For example, the resin layer 6 may be configured using a mixture of an inorganic filler and an organic resin such as an epoxy resin. The amount of the inorganic filler in the resulting mixture is preferably in a range of from 80% to 95% based on the total amount of the resin layer 6. The resin layer 6 is appropriate because adhesion thereof to the mounting member 1 is great.

In the semiconductor device according to this embodiment, the partition wall layer is provided on the mounting member along the outer periphery of the semiconductor chip, and thus undesired spreading of the solder is suppressed. Accordingly, it is possible to control the thickness of the soldering material between the mounting member and the semiconductor chip to a constant value or greater while suppressing the positional deviation or skew (in a case where one direction of a joining surface of the semiconductor chip is set as an X direction, a direction perpendicular to the X direction in the joining surface of the semiconductor chip is set as a Y direction, and a direction perpendicular to an XY direction is set as a Z direction, positional deviation in a rotational direction with the Z direction set as an axis) of the semiconductor chip in the rotational direction with respect to an axis that is perpendicular to the joining surface of the semiconductor chip.

After forming the partition wall layer 3 on the mounting member 1, the semiconductor chip 2 is placed on the solder paste on the mounting member 1, and the structure is heated to the reflow temperature of the solder paste to join the mounting member 1 and the semiconductor chip 2. At this time, if the partition wall layers 3 are not present the solder paste is often unevenly or non-uniformly distributed on the semiconductor chip side of the mounting member, and thus the position of the semiconductor chip 2 tends to be skewed or otherwise deviated from the desired position on the mounting member 1. In contrast, when the partition wall layers 3 are provided, the solder paste flows from the central region 11 toward the surrounding region 12, but the solder paste flow is blocked by the partition wall layer 3. Accordingly, a flow rate or a flow velocity of the solder paste is controlled. As a result, undesirable spreading of the solder from the mounting location of the chip 2 on the central region 11 of the mounting member 1 is suppressed.

In addition, since the open, i.e., unblocked by a partition wall layer 3, peripheral portions 12b are provided, a portion of the solder paste may flow therethrough from the central region 11 below the chip 2 during melting of the solder paste. Accordingly, when melting the solder, even in a case where the solder paste has an uneven or non-uniform thickness over the central region 11 of the mounting member 1, it is possible to eliminate this to uneven distribution of the solder by allowing excess solder paste to flow through the peripheral portions 12b. In addition, by suppressing the spreading of the solder by providing the partition wall layer, the available choices of the mounting member material which may be used is greater than in devices where the method of suppressing spreading of the solder is by processing a portion of the surface of the mounting member with a laser.

For example, in a lead frame having an exposed copper surface, as described above, the absorption rate of a high-frequency laser such as a YAG laser is low, and may be further reduced by the flux contained in the solder paste. Accordingly, a lead frame having an exposed copper surface is not suitable for the method of suppressing spreading of the solder by processing a portion of the surface of the mounting member with a laser. In contrast, in the method of suppressing spreading of the solder by providing the partition wall layer, even in a case of using the lead frame having an exposed copper surface as the mounting member 1, it is possible to sufficiently suppress spreading of the solder.

The shape and distribution of the partition wall layers 3 is not limited to the shape and distribution thereof illustrated in FIGS. 1 and 2. FIGS. 3 to 9 are schematic plan views illustrating other examples of a partition walls layers useful in forming the semiconductor device 10. In addition, in FIGS. 3 to 9, the lead portion 1b, the support pin portion 1c, and the bonding wire 5 are not illustrated.

In FIG. 3, the plurality of peripheral portions 12a include four first unit regions 121, each being provided at and extending along both sides of the semiconductor chip 2 at each corner of the semiconductor chip 2. The peripheral portion 12b includes four second unit regions 122, each being provided between the four first unit regions 121. The partition wall layer 3 includes four unit layers 30 which are provided on the four first unit regions 121 and have an L-shaped planar shape.

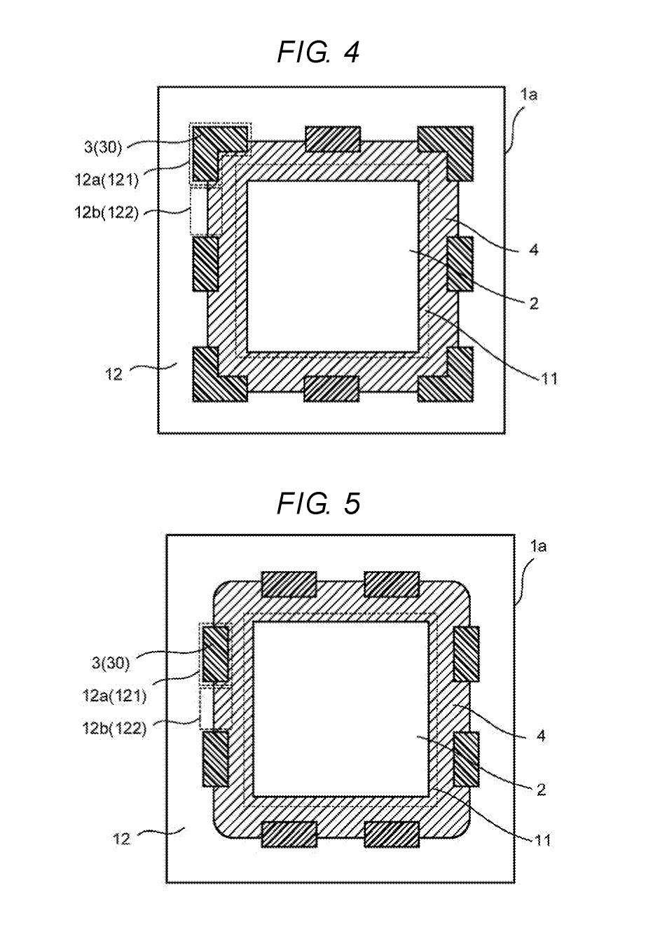

In FIG. 4, the plurality of peripheral portions 12a includes eight first unit regions 121, one of them provided adjacent to each side, and at each corner of the semiconductor chip 2 and along the adjacent sides of the semiconductor chip 2. The peripheral portion 12b includes eight second unit regions 122, each being provided between the eight first unit regions 121. The partition wall layer 3 includes four unit layers 30 adjacent to the corners of the semiconductor chip 2 and having an L-shaped planar shape, and four unit layers 30 having a rectangular planar shape, each being provided on one of the eight first unit regions 121.

In FIG. 5, the plurality of peripheral portions 12a include eight first unit regions 121, and two first unit regions 121 are provided adjacent to each side of the semiconductor chip 2, respectively. The peripheral portion 12b includes eight second unit regions 122, each extending between the eight first unit regions 121. The partition wall layer 3 includes eight unit layers 30 located on the eight first unit regions 121 and have a rectangular planar shape.

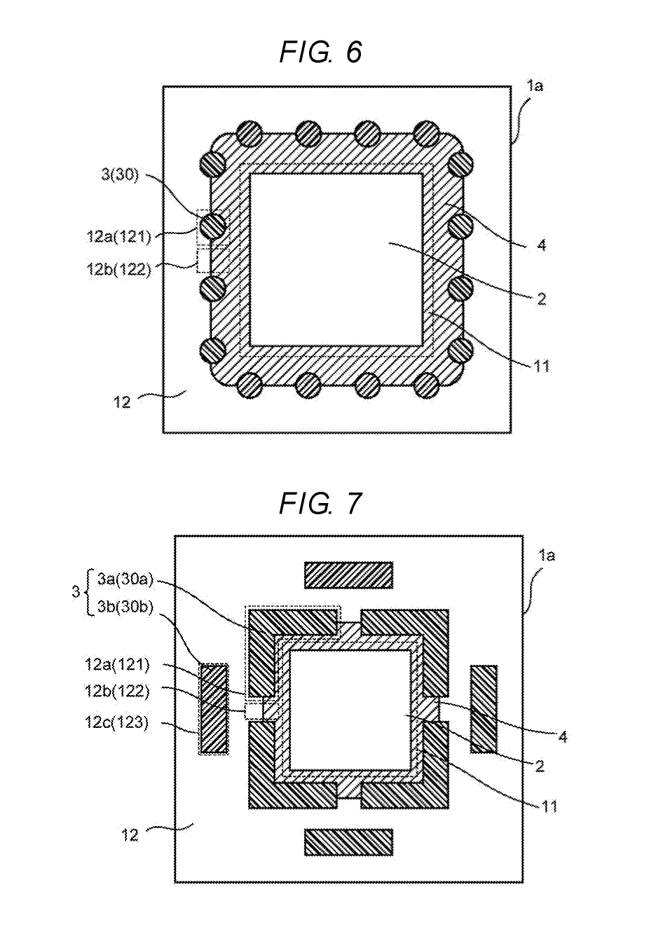

In FIG. 6, the plurality of peripheral portions 12a include sixteen first unit regions 121, and four first unit regions are located adjacent to, and evenly spaced apart from each other along, each side of the semiconductor chip 2. The peripheral portion 12b includes sixteen second unit regions 122, each one located between adjacent ones of the sixteen first unit regions 121. The partition wall layer 3 includes sixteen unit layers 30 which are provided on the sixteen first unit regions 12, and in plan view, have a circular shape.

As illustrated in FIGS. 3 to 6, by increasing the area of the peripheral portions 12b, the soldering material 4 can more readily flow from the central region 11 below the chip 2, and by increasing a ratio of the partition wall layers 3 to the peripheral portions 12b, the soldering material 4 is less able to flow from the central 11 region below the chip 2.

In FIG. 7, the surrounding region 12 further includes a plurality of peripheral portions 12c which are provided along at least the outer periphery of the peripheral portion 12b. The plurality of peripheral portions 12a includes four first unit regions 121, each being provided at each corner of the semiconductor chip 2, wherein the first unit regions extend along the sides of the chip 2 from the corner thereof. The peripheral portion 12b includes four second unit regions 122, each provided between adjacent ones of the four first unit regions 121. The plurality of peripheral portions 12c also include four third unit regions 123, each being provided alongside, and spaced from, each side of the semiconductor chip 2, such that a peripheral portion 12b is located between each of the peripheral portion 12c and the adjacent side of the chip 2. The third unit regions 123 may be regarded as peripheral portions 12c. The partition wall layer 3 includes a partition wall layer 3a including four unit layers 30a, one of which is provided on each of the four first unit regions 121 and have an L-shaped planar shape, and a partition wall layer 3b including four unit layers 30b one of which is provided on each of the four third unit regions 123 and have rectangular planar shape. The partition wall layer 3b (in FIG. 7, each of the unit layers 30b) extends along the outer periphery of the peripheral portion 12b (in FIG. 7, each of the unit regions 122).

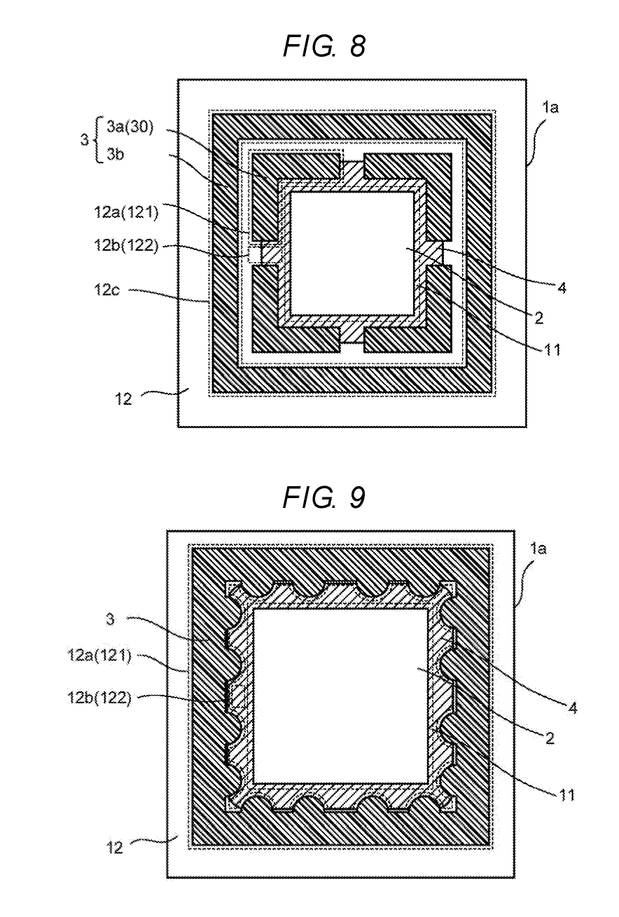

In FIG. 8, the surrounding region 12 further includes a peripheral portion 12c that surrounds the central region 11, the peripheral portion 12a, and the peripheral portion 12b. The plurality of peripheral portions 12a includes four first unit regions 121, one of each located at each corner of the semiconductor chip 2. The peripheral portion 12b includes four second unit regions 122, each located between the four first unit regions 121. The partition wall layer 3 includes a partition wall layer 3a including four unit layers 30, one of which are provided on each of the four first unit regions 121 and have an L-shaped planar shape, and a partition wall layer 3b provided on the peripheral portion 12c and surrounding the semiconductor chip 2, and which has an annular planar shape. The partition wall layer 3b is spaced from the partition wall layer 3a.

As illustrated in FIGS. 7 and 8, when the partition wall layer 3b is also provided on the peripheral portion 12c, even in a case where the soldering material 4 flows outwardly from the central region 11 through the peripheral portions 12b, it is possible to suppress undesired spreading of the solder.

In FIG. 9, the peripheral portion 12a surrounds the region 11. The partition wall layer 3 has an annular planar shape, and includes an inner wall including a plurality of convex portions extending therefrom around the central region 11 and which are spaced away from each along the inner perimeter of the partition wall layer 3. The shape of the convex portions is not particularly limited. The peripheral portion 12b includes a plurality of second unit regions 122, each being positioned at a gap or recess between adjacent convex portions. That is, the peripheral portion 12b extends along the inner perimeter of the partition wall layer 3 and into recesses between adjacent ones of the plurality of convex portions. When the convex portions are provided on the inner wall of the partition wall layer 3, it is possible to further enhance positional accuracy of the semiconductor chip 2 when mounted on the mounting member 1.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a mounting member comprising first and second regions, a plurality of first peripheral portions along at least a portion of an outer periphery of the first region, and a second peripheral portion between at least one of the plurality of first peripheral portions and another of the plurality of first peripheral portions, the plurality of first peripheral portions and the second peripheral portion located in the second region;
a first partition wall on at least one of the first peripheral portions; and
a semiconductor chip mounted on the first region via solder.

2. The device according to claim 1, wherein
the second region further includes a third peripheral portion along at least an outer periphery of the second peripheral portion, and
a second partition wall on the third peripheral portion.

3. The device according to claim 2, wherein the second peripheral portion is located between the third peripheral portion and the semiconductor chip.

4. The device according to claim 1, wherein
the first peripheral portion extends around the first region, and
the first partition wall extends around the first region.

5. The device according to claim 4, wherein
the first partition wall comprises an inner wall comprising a plurality of convex portions spaced from one another along the inner wall and forming gaps therebetween, and
the second peripheral portion extends inwardly of the gaps.

6. The device according to claim 1, wherein
the mounting member comprises an exposed copper surface, and
the first partition wall contacts the exposed copper surface.

7. The device according to claim 1, wherein a portion of the solder extends from the first region and into the second peripheral portion.

8. The device of claim 1, wherein the first partition wall has a thickness greater than a thickness of the solder.

9. The device of claim 1, wherein the first partition wall comprises at least one of an ink, a thermosetting resin, an ultraviolet curable resin, a polyimide resin, and an epoxy resin.

10. A method of forming a packaged semiconductor device, comprising:
providing a metal substrate having a surface including a chip mounting region and a peripheral region;
forming at least one wall extending outwardly from the surface of the metal substrate adjacent to the chip mounting region, wherein at least one open region of the metal substrate is located in the peripheral region directly adjacent to one end of the wall;
forming a solder layer on the chip mounting region;
positioning a substrate on the solder layer; and
heating the solder layer to at least a reflow temperature thereof, whereby solder flows outwardly from the chip mounting region and into the at least one open region of the metal substrate in the peripheral region.

11. The method of claim 10, further comprising:
providing a plurality of walls, wherein at least one wall of the plurality of walls is disposed adjacent to each side of the chip mounting region, and an open region extends between each adjacent wall.

12. The method of claim 11, further comprising:
forming an additional wall, wherein an open region is located between the additional wall and the chip mounting portion.

13. The method of claim 11, further comprising:
forming a non-uniform solder layer in the chip mounting region; and
flowing the solder to form a uniform thickness solder layer over the chip mounting region.

14. The method of claim 11, wherein the plurality of walls has a thickness greater than a thickness of the solder layer.

15. The method of claim 10, wherein the metal substrate comprises copper.

16. The method of claim 10, wherein the at least one wall comprises at least one of an ink, a thermosetting resin, an ultraviolet curable resin, a polyimide resin, and an epoxy resin.

17. The method of claim 10, wherein the at least one wall extends around the chip mounting region.

18. A semiconductor device, comprising;
a metallic mounting substrate having a mounting surface and a peripheral surface adjacent to the mounting surface; and
a wall positioned on the mounting substrate on the peripheral surface, the wall formed of a material other than the material of the metallic mounting substrate and including a plurality of openings therein;
a solder layer located on the mounting surface; and
a semiconductor chip connected to the solder layer.

19. The semiconductor device of claim 18, wherein a surface of the wall is repellant to solder.

20. The semiconductor device of claim 18, wherein the solder layer extends into at least one of the plurality of openings in the wall.
